(19) United States
(12) Patent Application Publication
(10) Pub. No.: US 2008/0100393 A1
(43) Pub. Date: May 1, 2008

(54) Low Power Direct Conversion Rf Transceiver Architecture and Asic and Systems Including Such

(75) Inventors: Peter R. Nuytkens, Melrose, MA (US); Joseph M. Kulinets, Stamford, CT (US)

Correspondence Address: BURNS & LEVINSON, LLP, 125 SUMMER STREET, BOSTON, MA, 02110, US

(73) Assignee: Custom One Design, Inc., Melrose, MA (US)

(21) Appl. No.: 11/579,005

(22) PCT Filed: May 2, 2005
(86) PCT No.: PCT/US05/15160

§ 371 Date: Jun. 21, 2007

Related U.S. Application Data
(60) Provisional application No. 60/567,133, filed on Apr. 30, 2004.

(51) Int. Cl. H04L 27/12; G05F 1/00; H03K 3/36; H04B 1/38; H02J 1/00

(52) U.S. Cl. 332/100; 323/282; 307/80; 331/46; 455/73

(57) ABSTRACT

A direct conversion RF transceiver (2) and ASIC having an on-chip voltage controlled oscillator operating frequency that is half of the transmitter (4) and/or receiver (6) operating frequency, the VCO (20) being comprised of a plurality of synchronized LC oscillators (92A-D) introducing precise phase shifts that eliminate frequency ambiguity. The transceiver incorporates several low power circuits, including on-chip a power converter switchably coupling a capacitor (42) to a power supply (45) and to an electrical load (40), multiple switchable low dropout regulators (60A, B) each coupled to alternate power supplies (62,64) and having electrical components (67A, B) for setting the bandwidth of the respective low dropout regulator. The transceiver also includes a FSK digital modulator utilizing a circuit-implemented polynomial piecewise approximation (71) of a raised cosine signal.

### BACKGROUND OF THE INVENTION

The present invention relates generally to low power transmitters, receivers, and transceivers for transmitting and receiving digital information between two or more digital devices, and more particularly to embodiments of multi-band RF transceivers that can be implemented preferably on a single chip and/or for use in applications involving remote reading of metering equipment.

A variety of industries require transmitting and receiving digital circuitry to meet strict power consumption requirements in order to be useful in battery-operated and power-sensitive applications. Examples of such applications include narrow-band & wide-band security systems, voice and data over radiofrequency (RF) links, process and building control, parking & traffic enforcement monitoring, access control, home automation, home appliance interconnections.

In utilities industries, for example, it is often necessary to send employees to customer sites to take physical readings from digital equipment such as, for example, utility meters. This can present challenges in terms of access. Circumstances such as bad weather, vegetation, inaccessible landscapes, animals and/or alarms may prevent meter readers from performing their tasks on their first attempt, and may make their jobs more hazardous. Rescheduling appointments or needing to repeat trips to customer sites increases costs and lowers productivity. Telemetering, wherein such meters are read remotely with the use of network-based and/or wireless communications has been a rapidly developing field. In aircraft avionics systems, there may exist a number of remote digital sensing devices that are equipped with transceivers for reporting telemetry/operational parameters such as speed, direction, fuel levels, temperatures, wind velocities and the like. Radiofrequency (RF) RF transceivers such as those employed in utility telemetering applications are often portable and battery operated. Thus, the efficient use of power by the digital circuitry of such instruments is critical to prolonged battery life and overall success.

This broad statement is true not just in battery-powered transceivers, wherein short boosts of DC power are needed (especially during wireless data transmissions), but in any DC-DC power converter circuit wherein it is a requirement to generate short bursts of higher power than can be instantaneously drawn from a low voltage power supply. It is therefore one objective of the present invention to address such needs.

A number of the applications for RF transceivers noted above, as well as others not discussed, demand not only higher power consumption and conversion efficiency, but also a higher level of physical integration than is currently achieved, in order to meet associated size constraints. A number of electrical circuits that comprise RF transceivers such as, for example, DC-DC converters, RF filters and varactors, are often implemented “off-chip”, i.e., not integrated within a single application specific integrated circuit (ASIC.) This results in more space being required for such components (typically on the same printed circuit board (PCB) upon which the ASIC is mounted) within the RF communications device. What is needed, then, is an integrated, compact and robust data communication system including a power efficient transceiver providing reliable communications for a variety of users in commercial and industrial environments.

### SUMMARY OF THE INVENTION

Accordingly, it is a primary object of the present invention to provide a multi-band (mask tunable) RF transceiver design with a significantly enhanced feature set that operates with reduced power requirements. It is also an object of the invention to provide digital communications systems incorporating such transceivers.

The features set forth below are achieved individually and in combination, and it is not intended that the present invention be construed as requiring two or more of the features to be combined unless expressly required by the claims to be decided upon at a later time. These features, however, may all be integrated in a single transceiver ASIC.

In accordance with the present invention, a compact, battery-powered wireless data transceiver is adapted to establish and maintain communication links at multiple frequencies across a 433 MHz-1.2 GHz spectrum with a range and data rate useful in a wide variety of applications (e.g., remote utility and parking meter reading, cordless phone operation, etc.)

The transceiver of the present invention operates at very low power and very low voltages under microcontroller supervision. The transceiver is equipped with a highly efficient (˜92% for 1.5V/3.5V) on-chip DC-DC converter that works down to a battery voltage of 0.6V and with a power boost for transmitting operations. Extremely long battery life is achievable through the unique design elements. The system uses on-off-keyed (OOK) modulation and frequency shift keyed (FSK) modulation in receiving and transmitting modes.

The transceiver also includes an ultra-fast locking programmable synthesizer with on-chip voltage controlled oscillator (VCO) and phase locked loop (PLL) with a typical output frequency resolution of less than 10 Hz. It is capable of extremely fast tuning and lock at the required frequency with use of a fractional-N divider without fixed pre-scaler divider.

### BRIEF DESCRIPTION OF THE FIGURES

For a better understanding of the present invention, together with other and further objects thereof, reference is made to the accompanying drawing and detailed description, wherein:

FIG. 1 is a schematic diagram of an RF transceiver in accordance with one embodiment of the invention;

FIGS. 2A-2C are block diagrams of alternative embodiments of DC-DC boost converters in accordance with the invention;

FIG. 3 is a block diagram of a dual LDO circuit in accordance with the invention;

FIG. 4 is an exemplary plot of frequency modulation plan;

FIGS. 5A-5D are plots of signals related to a digital frequency modulator;

FIG. 6 is a block diagram of a FSK modulator;

FIG. 7 is a clock diagram of a circuit for generating a raised cosine approximation signal;

FIG. 8 is a diagram of a quadrature VCO in accordance with one embodiment of the invention;

FIGS. 9A-9C are plots of phase-shifted outputs of a VCO in accordance with one embodiment of the invention;

FIG. 10 is an illustration of bandwidth shifting in accordance with a range-finding algorithm.

### DETAILED DESCRIPTION OF PREFERRED EMBODIMENTS OF THE INVENTION

The RF transceiver architecture described below has been integrated within a single chip for use in telemetering systems and provides multi-band (a single metal mask layer change to tune transceiver to frequencies such as 429 MHz, 952 MHz, 1.2 GHz or 1.43 GHz), battery powered functionality in a small package size (e.g., 9 mm×9 mm or smaller). The ASIC works under microcontroller supervision and provides an on-chip DC-DC converter with novel power boost circuitry to meet increased amperage demands for transmitter power supply during transmission. The DC-DC converter described below significantly prolongs battery life for portable transceivers in which the RF transceiver is utilized, and allows use of low voltage power supplies (e.g., battery voltages to 0.6V.)

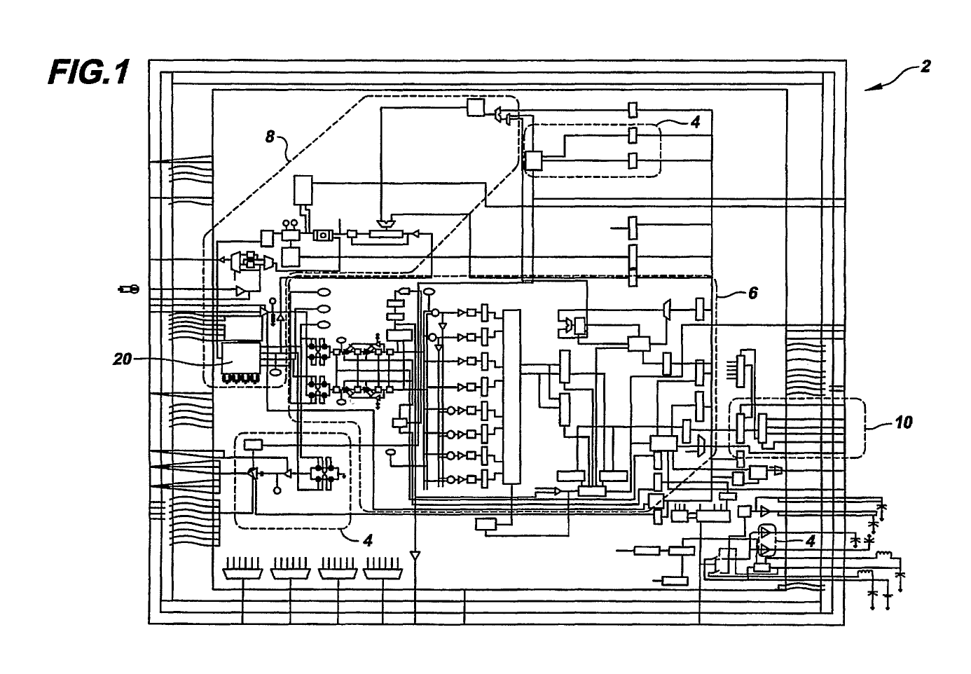

As shown in the architecture of FIG. 1 the RF transceiver 2 is comprised of the following major circuits: transmitter circuitry (encircled by a dotted line 4); receiver circuitry (encircled by a dotted line 6) including an automatic frequency controller a digital demodulator and a Manchester decoder; a shared digitally controlled frequency oscillator (a fractional-N frequency synthesizer encircled by a dotted line 8); and an interface and programming block 10 which includes a conventional microcontroller and logic for operating the transceiver. The transceiver employs frequency shift keying (FSK) and on-off keying (OOK) operation during transmit and receive.

The transceiver also employs an ultra-fast locking programmable synthesizer with on-chip voltage controlled oscillator (VCO 20) and a PLL having a high degree of frequency resolution (i.e., less than 10 Hz.). The receiver 6 converts an incoming 2-level (binary) FSK modulated signal into a synchronized bit stream. The receiver 6 employs a direct-down conversion (or zero-IF) architecture, where the RF signal is directly demodulated into base-band. The RF signal first goes through a LNA for primary amplification, and the output of the LNA passes through sub-harmonic mixer. The function of LNA is to amplify the incoming RF signal and match the expected 50-Ohm input impedance. The LNA was fabricated using a CMOS cascade architecture with source inductance degeneration. The I/Q signals then pass through a low pass filter (LPF) and an analog to digital converter (ADC) before entering a FSK demodulator. Each receiver ADC is essentially a limiter follower by a comparator.

The sub-harmonic mixer uses a local oscillator (LO) signal that is a fraction (e.g. ½) of the desired down-conversion frequency f_{C}. Using a sub-harmonic mixer in the direct conversion receiver reduces the LO self-mixing problem because the frequency of the RF signal and the LO signal frequency will be different. Any LO signal that leaks to the input of the mixer will be mixed to a frequency outside of the signal band. Another potential advantage of a sub-harmonic mixer is that since the LO signal is at a lower frequency, it may reduce the difficulty of designing buffers for the VCO and LO. Four LO signals are utilized in the embodiment described below to achieve a frequency conversion of 2f_{LO} to IQ base-band signals. Thus, the architecture includes a quadrature oscillator VCO 20 with 0, 45, 90, and 135 degree phase shifts at half the RF frequency, and achieves low leakage from the VCO to the RF input, and low-noise LNA architectures. The FSK demodulator converts I/Q outputs into a data stream. The I/Q outputs are demodulated by determining the direction of phase rotation using a differentiator and digital integrate and dump block.

The transmitter circuitry 4 performs the direct 2-FSK modulation of the carrier signal by an input bit stream and the transmission of the modulated signal. The modulation is accomplished using a digital modulator together with a fractional-N frequency synthesizer. The transmitter mixer is a sub-harmonic double-balanced mixer and is designed to operate with the on-chip VCO 20. Since the transceiver employs a constant envelope modulation scheme (GFSK), it is possible to use class AB or B power amplifier output stages (instead of the high linearity class A) to obtain better power added efficiency (>40%) values. The use of class C or E output stages can be limited by the low gate oxide breakdown voltage of FETs in target technologies when using 3V supply voltages. For 1.5 V supply voltage (after DC/DC conversion) a high efficiency class C or E output stage implementation is possible.

The frequency synthesizer uses a PLL and a fractional N-divider. This architecture provides more accurate tuning because of the ratiometric presentation of ratio of required and reference frequencies. The architecture also uses the direct N/N+1 divider without a pre-scaler. As a result, the comparison at the frequency detector/phase detector is performed at the f_{REF} (e.g., 16 MHz) which significantly reduces frequency lock time, brings down f_{REF} spurs, and increases the accuracy of frequency tuning. A reference oscillator provides the frequency synthesizer internal clock, and allows operation with a suitable external crystal, between 8 MHz and 20 MHz. An external oscillator may be used to supply the reference clock frequency of between 5 MHz and 20 MHz.

VCO 20 includes at least one internal varactor, as will be described below. The frequency synthesizer PLL uses a classical charge pump into an external loop filter, in which the filter output connects to the voltage tuning input of the VCO. The XOR phase detector and charge pump together with an external loop filter tank produce a mean output current that is proportional to the phase difference between (non-divided) reference frequency f_{REF} and the f_{VCO} divided by programmed fractional N value.

FSK modulation is well known in the art, so it is not believed necessary to present a detailed description beyond the advantageous features of the preferred embodiment described above and below. (see the IEEE 802.15.4 Low Rate Wireless Personal Area Network standard, which is incorporated herein by reference.)

### DC-DC Boost Converter Circuit

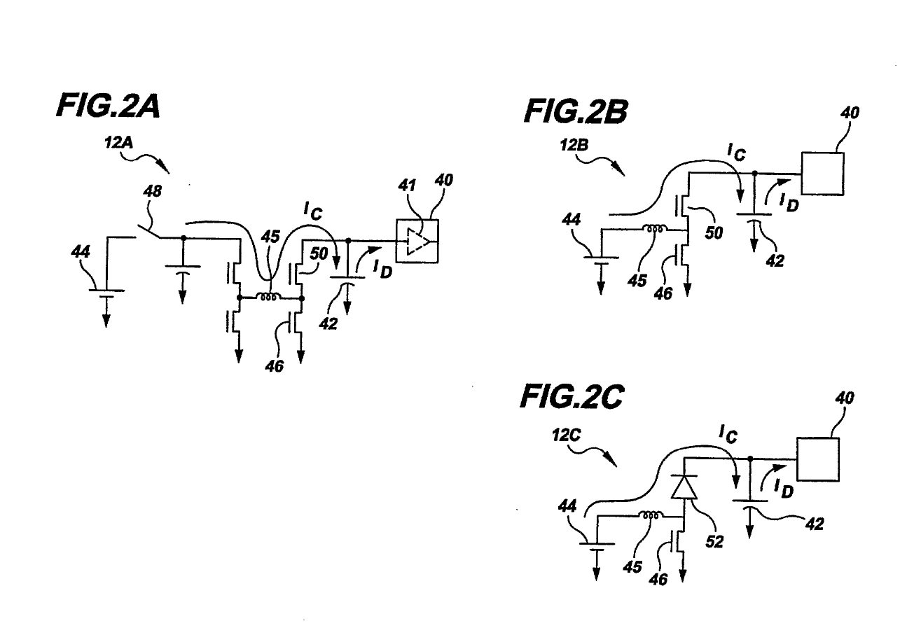

As with any of the architectures described above, the level of integration on an ASIC is dependent on the requirements of the intended application. In the fully integrated embodiment of the transceiver architecture 2, synchronous boost converters 12A-12C, as shown in FIGS. 2A-2C, may be employed rather than connecting directly to a battery. The on-chip DC-DC boost converter architectures can supply up to 5.8V or higher DC output for all the other circuitry on the transceiver's printed circuit board, and can be designed for any load 40, such as the transmit power amplifier 41 of the transceiver.

The receiver architecture determines a power supplying battery's lifetime in the transceiver, however the transmitter demands relatively high bursts of power for a relatively short period of time (e.g., 1 Amp for about 20 msec.) In order to supply higher instantaneous power to the load 40, a capacitor 42 is supplied a charge current I_{C}, through an energy storage element such as, for example inductor 45, during a charging phase from a battery 44 or any other low voltage power supply (e.g., solar cells integrated within a portable device, an external low voltage supply source, etc.) Then, a current I_{D} is discharged in a discharge phase when the power is required (i.e., during transmit mode.)

Several alternative embodiments of the boost converter circuit integrated on the ASIC are illustrated in FIGS. 2A-2C. In FIG. 2A, the charging current from the battery 44 can be shut off (by opening switch 48) or shunted to ground (through FET 46) while capacitor 42 discharges into the load 40. As shown in FIG. 2C, a diode 52 may be used in place of FETs 50 in switchably controlling the flow of current from the power supply 44 to capacitor 42. In conventional power amplifier supply circuits, the charging capacitor would be directly connected to the power supply through a switch.

FETs 46 and 50 are driven by non-overlapping clocks, on one half of the clock cycle energy is transferred from battery 44 to inductor 45, and on the other half of the clock cycle energy is transferred from the inductor 45 to the capacitor 42. Also, inductor 45 could be replaced with any energy storage element, including a capacitor.

In a non-limiting example, if the capacitance of capacitor 42 is on the order of 10 mfarad, and the transceiver power amplifier 41 requires about 1 Amp at 2.7V DC, then a transmission of approximately 20 mseconds can be obtained, which allows roughly 200 bits of data to be transmitted per transmission burst. This is sufficient for most telemetry applications, as data compression techniques are often employed. A 3.6V battery power supply 44 will be able to recharge capacitor 42 under such conditions in about 1 second. Although the description provided includes a load that requires a higher voltage than is provided by the power supply, component selection and switching can be varied to meet needs wherein a lower voltage is needed by the load.

The architectures described above permit longer transmission times than conventional buck converters, and result in charge current I_{C} being drawn from battery power supplies at a controllable, constant rate, which is highly recommended by battery manufacturers. In the conventional systems described above, the charge current being drawn from the battery will not be controllable and the duration of the transmission will be limited to the voltage present on the battery.

### Low Dropout Regulator With Selective Power Supply

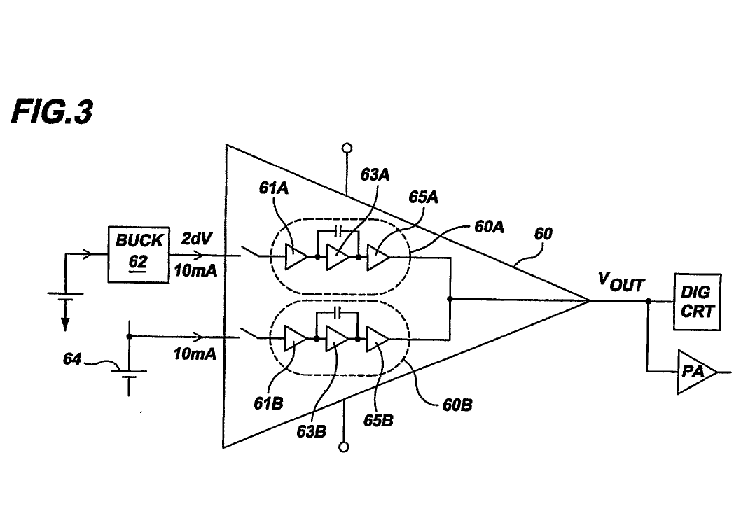

With reference to FIG. 3, another feature of the on-chip DC-DC converter is the use of two switchable low dropout regulators (LDOs) 60A and 60B to permit selective use of power from the buck converter 62 or from the battery 64 directly. Each LDO 60A, 60B is comprised of three stages connected in series. Each LDO has a first input stage (61A, 61B) that is that compares the output voltage V_{OUT} of the LDO 60 to a reference voltage and provides a corrected input to the second stage (63A, 63B.) Each second stage (63A, 63B) is a gain stage (power transistor) that provides current gain according to the desired level of output at LDO 60. Each third stage (65A, 65B) provides the output signal of LDO 60 at the required impedance. LDOs 60A and 60B (higher voltages) are each optimized for their respective input power.

Power supplied from a buck converter has a higher efficiency, but has a larger noise component, while on the other hand power supplied from the battery is cleaner but less efficient. The bandwidth of each LDO 60A, 60B is controllable by a feedback element, such as capacitors (67A, 67B). A lower capacitance may introduce instability in the LDO 60 depending on the load, but results in better high frequency filtering. Conversely, a higher capacitance results in very stable LDO output but has reduced high frequency filtering capability. The capacitors 67A, 67B may be variable in order to shape the noise characteristics. In certain embodiments the element consists of an inductive element.

### Digital, Programmable Raised Cosine Frequency Modulator

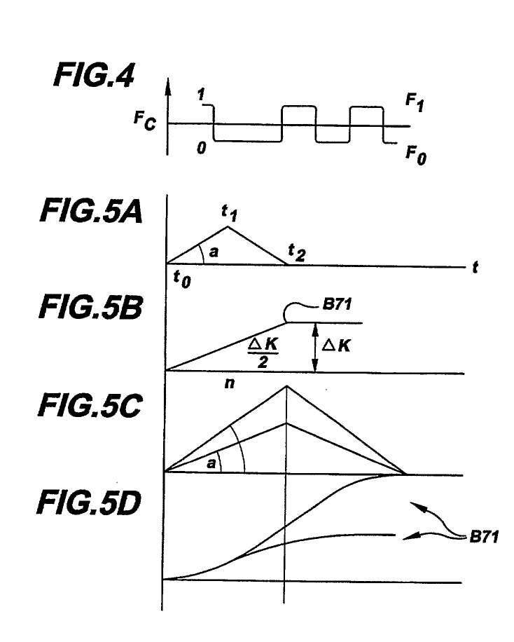

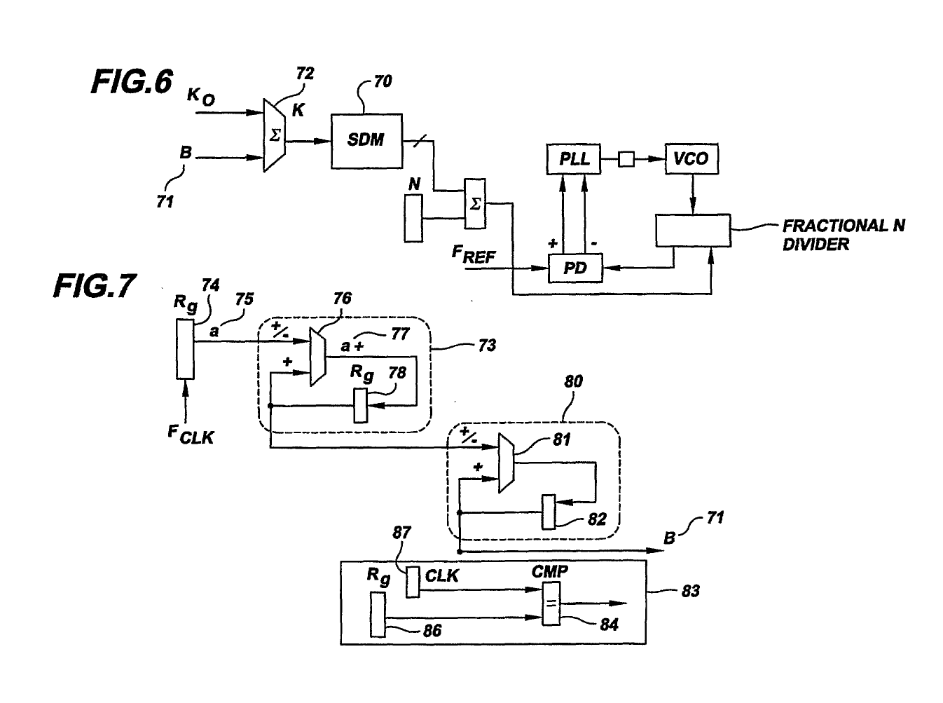

With reference to FIG. 4, in binary FSK modulation, signal frequencies are shifted between a first frequency f₀, representing a binary value 0, and a second frequency f₁, representing a binary value of 1. In the simplified block diagram of the FSK digital modulator shown in FIG. 6, the frequency switching is controlled by a signal K that is output from adder 72 and fed into digital Sigma Delta Modulator 70. Signal K is the summed output of a constant value K₀ and a controllably time-varying signal B 71. As is also recognized in the art, in order to switch smoothly between modulation frequencies, it is desirable to generate signal B 71 such that it approximates a raised cosine function. Signal B provides a difference between K₀ and K₁, which produce f₀ and f₁, respectively.

In conventional systems, the curve of B is simulated discretely through stepped values. The circuit shown in FIG. 7, however, allows a programmable, polynomial piecewise approximation of a raised cosine signal to be generated, with control over each of the signal characteristics that comprise the approximated cosine signal. Register 74 outputs with each clock cycle n a constant signal a 75 which has a controllable positive (+) or negative (−) value. Signal a 75 is fed into a first digital integrator 73, comprising summer 76 which accepts as its other input the output of a register 78 that, in turn, accepts as input signal ax 77 output from summer 76. Depending upon whether a 75 is positive or negative, the output of register 78 will be a linearly increasing or decreasing value (such as shown in FIG. 5A). The output of integrator 73 is then, in this second order approximation embodiment, fed into a second integrator 80, which is similarly comprised of a summer 81 coupled at its output to a second register 82. The output B 71 of second integrator 80 is then fed into summer 72 of the FSK digital modulator of FIG. 6.

The control of n (the number of clock signals before switching the sign of a 75), the amplitude and sign of a 75, and the clock frequency F_{clk} permit shaping of the approximated raised cosine signal B 71. With reference to FIGS. 5A and 5B, it can be seen that while signal a 75 is positive and increasing (from t₀ to t₁), signal B 71 starts increasing with a controlled second order polynomiallly shaped curve. When the sign of a 75 is changed (by control block 83) from positive to negative (from t₁ to t₂), signal B 71 starts smoothing off. After t₂, when no signal a 75 is applied, signal B 71 levels off at an amplitude K (the difference required to switch from f₀ to f₁ in the frequency domain.) As shown in FIGS. 5C-5D, a greater value of signal a 75 results in a steeper slope of signal B 71, as the shape of the curve in this second order approximation is governed by the equation at². The number of clock cycles is determined by the required bit rate, and the coefficient a 75 is calculated based upon the known number of clock cycles n and the known difference between the constants K₁ and K₀. K is in a range between −1 and +1, and the frequency of the VCO is equal to the product of outside reference clock frequency F_{ref} and (N+K).

Control block 83 comprises a comparator 84 which compares a predetermine number of clock cycles stored in register 86 to the output of a clock counter 87 to determine when to switch the sign of a 75 and when to stop the modulation process. When the midpoint of the rise (or decline, in downward sloping portions) of the curve of signal B 71 (i.e., at t₁) is determined by the comparator to be attained, the sign of signal a 75 is switched from positive to negative (or vice-versa in downward sloping portions) to effect a smooth, leveling-off of the curve of signal B 71. By making the frequency shift ‘softer’, the frequency spectrum can be made significantly narrower, thus, higher data rates can be transmitted in the same bandwidth. It should also be noted that the approximation achieved by the circuit described could be extended to Nth order approximations by using higher order integrators.

### Quadrature VCO With Controlled Oscillator Start-Up

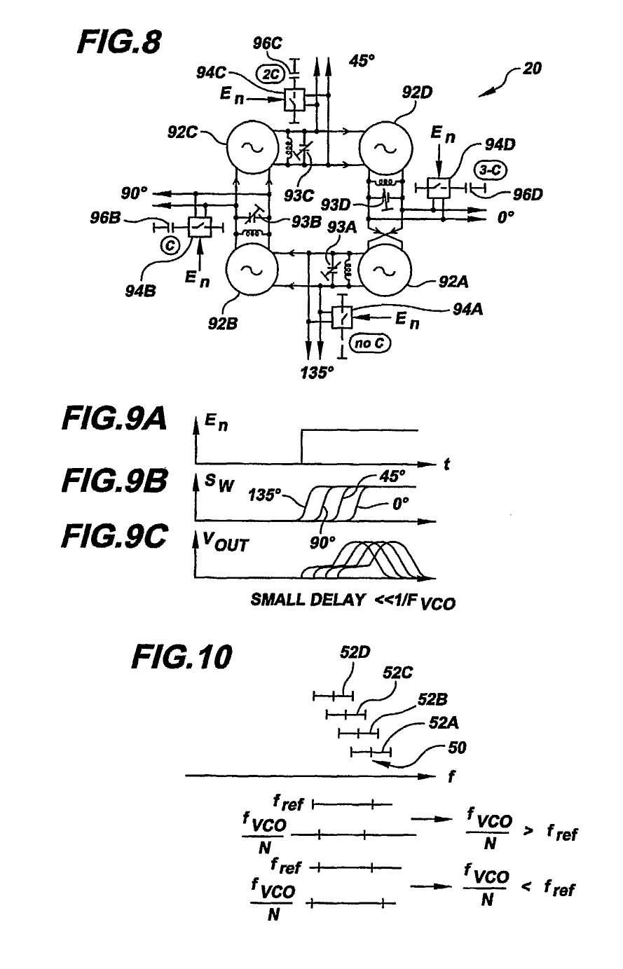

With reference to FIG. 8, the RF transceiver employs a VCO 20 that is comprised of four identical LC oscillators 92A-92D in electrical connection, each of the oscillators including an associated varactor 93A-93D whose capacitance changes with a control voltage to assist in obtaining the desired VCO frequency f_{VCO}, and each able to produce, respectively, phase shifts of 135°, 90°, 45° and 0°. The connection between 92D and 92A includes a 180° phase shift. Similar VCO structures are known in the art, but without the present circuit for controlling the direction/sequence of rotation at oscillator start-up. (see “A 10-GHz CMOS Quadrature LV-VCO for Multirate Optical Applications”, IEEE Journal of Solid State Circuits, Vol. 38, No 10, October 2003, the contents of which are incorporated herein by reference.) If the four oscillators were connected without the inventive feature, for example, a phenomenon sometimes referred to “frequency ambiguity” may be introduced, wherein two different steady states, one with all phase shifts positive and one with all shifts negative would be possible. However, the wrong steady state could result in switched I and Q on the output of the mixer.

Associated with each oscillator 92A-92D, connected in parallel with the respective output of the oscillator, is a normally closed switch 94A-94D enabling a shunt of the output of that oscillator to ground. In addition, connected in series with each of switches 94C-94D, is a capacitor 96C-96D having a capacitance particularly related (by multiple) to a capacitor 96B connected in series with switch 94B. There is no such capacitor connected to switch 94A. Upon an enable pulse Eₙ intended to trigger the opening of switches 94A-94D, as a result of the different values of capacitors 96B-D (and the lack of a capacitor at oscillator 92A), the switches open at different times, as reflected in timing diagrams of FIGS. 9A-9C. The desired timing of phased output and “rotation” among the oscillators 92A-92D is achieved through judicious selection of the capacitance values of the capacitors 96B-96D. The selection is related to the number of oscillators comprising the VCO 20. In this quadrature LC oscillator embodiment, the capacitors' values are chosen to have ratios of C (96B), 2C (96C) and 3C (96D), respectively.

This assures that the output of oscillator 92A, with a phase shift of 135, releases the first output from VC) 20, which is followed by the output of oscillator 92B, with a phase shift of 90 degrees, and so on, as reflected in FIGS. 9B and 9C. Those of skill in the art will appreciate that the ordered rotation among the oscillators could, with minor changes, be caused to rotate in the opposite direction (with some occasional noise.) It should also be noted that this approach is generally extendable to VCO architectures having lesser or greater numbers of LC oscillators with phase shifts related to the number of LC oscillators, according to the formula (180°/# of oscillators.)

### VCO Frequency Range-Finding Algorithm

In order to obtain the desired f_{VCO} for the VCO 20, the RF transceiver employs a range finding control algorithm for iteratively shifting the f_{VCO} by comparing f_{VCO}/N to the reference frequency f_{REF}. Each of the four LC oscillators contains a digitally controlled bank of capacitors and varactors (at least one) connected in parallel (not shown) that help determine the oscillating frequency of the oscillator. In the RF transceiver fabricated by the applicants, the bank consists of 31 capacitors and one varactor. The general principle of the approach is that, in an iterative fashion, additional capacitors are connected (lowering f_{VCO}) until a frequency condition of f_{VCO}/N switches from a condition (f_{VCO}/N >f_{REF}) to (f_{VCO}/N<f_{REF}) as determined by two frequency detectors.

With reference to FIG. 10, the process begins by ‘freezing’ the sigma delta modulator and the PLL is discharged, so that the f_{VCO} /N frequency monitored is know to be in the middle 50 of the incremental bandwidths 52A-52D being successively searched. The output from the VCO N−divider is compared to f_{REF} with a first capacitor turned on. A first phase detector (not shown) indicates whether the condition (f_{VCO}/N>f_{REF}) is confirmed, and if it is, as expected, an additional capacitor is turned on. This has the effect of shifting the frequency bandwidth of the VCO from 52A to 52B, and thus the f_{VCO}/N frequency being compared to f_{REF}. The process continues, with successive connections of additional capacitors until the frequency condition switches from (f_{VCO}/N>f_{REF}) to (f_{VCO}/N<f_{REF}), at which point the control algorithm ends, having attained the desired f_{VCO}. The shifting bandwidth is narrow enough to assure operation within an acceptable frequency range.

A self-contained transceiver architecture with power conservation features, which has been fabricated on a single ASIC, has been described which requires a minimal number of external components or bias supply. Although the invention has been described with respect to various embodiments, it should be realized this invention is also capable of a wide variety of further and other embodiments within the spirit of the invention.

We claim:

1. A DC-DC boosting power converter, comprising:
a capacitor coupled to an electrical load so as to supply power to the electrical load;
integrated on an ASIC, circuitry for switchably coupling the capacitor through an energy storage device to a power supply during a first phase so as to charge the capacitor, and for de-coupling the power supply from the capacitor during a second phase so as to discharge the capacitor into the electrical load.

2. The DC-DC converter of claim 1, wherein the load is an integrated circuit requiring a higher V than which the power supply supplies.

3. The DC-DC converter of claim 1, wherein the power supply is a battery or solar cell.

4. The DC-DC converter of claim 1, wherein the load is a power amplifier or motor drive.

5. The DC-DC converter of claim 1, wherein the capacitor is charged at a constant rate.

6. In a DC-DC power converter, circuitry for switching between power sources, comprising:
a buck converter providing DC power;
a battery providing DC power;
integrated on an ASIC, two switchable low dropout regulators, each having an input switchably coupled to one of the buck converter or the battery, and each having an output commonly coupled to a load, and each having an element for setting the bandwidth of the respective low dropout regulator.

7. The DC-DC power converter of claim 6, wherein the element is a capacitor or inductor.

8. The DC-DC power converter of claim 6, wherein the element is a variable capacitor.

9. In a FSK digital modulator, a circuit implemented polynomial piecewise approximation of a raised cosine function.

10. The circuit of claim 9, wherein the polynomial is of the Nth order, wherein N is a second order or greater.

11. A voltage controlled oscillator, comprising:
N identical LC oscillators in electrical connection, each providing 180/N degree phase shifts;
circuitry associated with each LC oscillator such that a common enable signal starts the LC oscillators in a predetermined order to eliminate frequency ambiguity.

12. The VCO of claim 11, wherein the operating frequency of the VCO is determined by means of a range finding algorithm.

13. An RF transceiver architecture having a VCO operating frequency that is half of the transmitter operating frequency.

14. An RF transceiver architecture having a VCO operating frequency that is half of the receiver operating frequency.
